(19) United States
(12) Patent Application Publication
(10) Pub. No.: US 2026/0118401 A1
(43) Pub. Date: Apr. 30, 2026

(54) METHOD FOR RAPID DETECTION OF POWER CABLE FAULTS

(71) Applicant: Siyuan Yan, Xianyang (CN)

(72) Inventor: Siyuan Yan, Xianyang (CN)

(21) Appl. No.: 19/191,338

(22) Filed: Apr. 28, 2025

(30) Foreign Application Priority Data
Oct. 28, 2024 (CN) 2024115094861

(51) Int. Cl. G01R 31/11; G01R 31/08

(52) U.S. Cl. CPC G01R 31/11; G01R 31/083

(57) ABSTRACT

A method for rapid detection of power cable faults. Based on the principle of pulse reflection, this method involves sending a high-frequency, short pulse signal into the underground buried power cable, receiving the echo signal reflected back from the fault point at the other end; by measuring time difference between the emitted signal and the received echo signal, and combining the known propagation speed of the signal in the cable, the precise location of the fault point can be accurately calculated. This method avoids the complexity and time consumption of traditional manual detection, greatly improving detection efficiency and accuracy; auxiliary techniques such as electromagnetic induction and acoustic detection are used to further narrow the search range, achieving the precise localization of the fault point. This method is applicable to underground buried power cables of various types, specifications, and materials, offering high efficiency, accuracy, and precise identification of fault points.

### TECHNICAL FIELD

The invention relates to the technical field of power system maintenance and detection, in particular to a rapid detection method for sudden faults in underground buried power cables during operation. The invention aims to provide a non-excavation, efficient, and accurate fault detection means for power cables to quickly locate and repair fault points and restore power supply.

### BACKGROUND ART

Power cables, as important infrastructure for power transmission. The safe and stable operation of power cables plays a crucial role in ensuring the reliability of power supply. However, during actual operation, cables may experience sudden faults due to various reasons (such as aging, overload, or cable quality issues), leading to power outages. Traditional fault detection methods mainly rely on manual inspections along the cable route. This approach is not only time-consuming and labor-intensive, but also limited in accuracy, especially in complex terrains or hard-to-reach areas, such as corners and bends, where detection is extremely difficult. This significantly impacts the speed of fault repair and the efficiency of power restoration.

### SUMMARY OF THE INVENTION

In order to address the problems in the existing technology, the invention proposes a method for rapid detection of power cable faults. This method is based on the principle of pulse reflection. By sending a pulse signal into the cable, utilizing the characteristic of the signal propagating through the cable and reflecting at the fault point, and combining the time difference calculation, the method achieves the accurate localization of the fault point.

In order to realize the above objects, the invention is realized by the following technical scheme.

A method for rapid detection of power cable faults comprises the following specific steps:
a) pulse signal emission: a high-frequency, short pulse signal is emitted into a power cable to be tested by using a pulse generator, the signal propagates along a cable conductor and reflects when it encounters a fault point, forming an echo signal;
b) echo signal reception: a receiver is placed at the other end of the cable or at an appropriate location, the receiver is used to capture the echo signal reflected from the fault point in the cable and record the time the pulse signal was transmitted and the time the echo signal was received;
c) time difference calculation and distance determination: based on the known propagation speed of the pulse signal in the cable, calculate the time difference between the transmitted pulse signal and the received echo signal, and then calculate the actual distance from the fault point to one end of the cable;
d) precise localization of the fault point: by combining a cable layout map and the distance information calculated in step c), along with auxiliary means such as electromagnetic induction and acoustic detection, further narrow down the search area to directly determine the precise location of the fault point.

Further, this method is applicable to underground buried power cables of various types, specifications, and materials.

By implementing the method of the invention, the following effects can be achieved:
1. enhancing detection efficiency: compared with traditional manual detection methods, this invention significantly shortens detection time and improves detection efficiency;
2. improving localization accuracy: by calculating the time difference, precise localization of the fault point is achieved, reducing the possibilities of misjudgment and missed detection;
3. reducing maintenance costs: it avoids large-scale excavation and labor intensive work, thereby lowering maintenance costs and minimizing environmental impact;
4. enhancing power supply reliability: rapid localization and repair of the fault contribute to swift restoration of power supply, improving the stability and reliability of the power system.

### BRIEF DESCRIPTION OF ACCOMPANYING DRAWINGS

FIG. 1 is a flowchart of the implementation of a method for rapid detection of power cable faults of the invention.

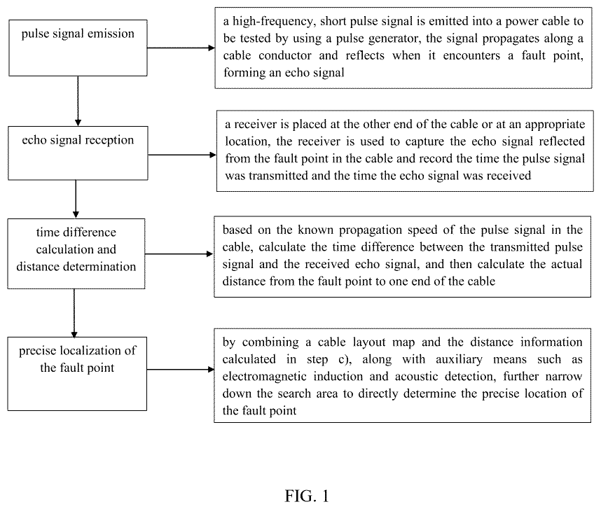

### SPECIFIC EMBODIMENT OF THE INVENTION

In order to make the objects, technical schemes and advantages of the embodiments of the invention clearer, the technical schemes in the embodiments of the invention will be clearly and completely described below in combination with the accompanying drawings in the embodiments of the invention, obviously, the described embodiments are some, but not all embodiments of the invention. The components of the embodiments of the invention generally described and illustrated in the drawings herein may be arranged and designed in a variety of different configurations.

### EMBODIMENT

Principle: this technical scheme utilizes the propagation characteristic of pulse technology in the cable. A pulse signal is sent into the cable, and the signal propagates along the conductor inside the cable. When it encounters a fault point (such as a break, short circuit, etc.), it is reflected, forming an echo signal. By measuring the time difference between the transmitted signal and the received echo signal, and combining the propagation speed of the signal in the cable, the location of the fault point can be accurately calculated.

### Steps of Technical Scheme

### 1. Preparation Stage

Confirm the model, specification, and material of the cable to be tested, as well as the cable's installation path and length.

Prepare the testing equipment, including a pulse generator, a receiver, a signal processor, etc., and ensure that the equipment is in good working condition.

Connect the pulse generator to one end of the cable and the receiver to the other end, ensuring a good connection between the equipment and the cable.

### 2. Pulse Signal Emission

Use the pulse generator to emit a high-frequency, short pulse signal into the cable.

Record the time of pulse signal emission for subsequent time difference calculations.

### 3. Echo Signal Reception and Processing

The receiver captures the echo signal reflected from the fault point in the cable.

Record the time when the echo signal was received and calculate the time difference between the transmitted pulse signal and the received echo signal.

Use the signal processor to filter and amplify the received echo signal to improve the signal-to-noise ratio and clarity.

### 4. Distance Calculation and Fault Point Localization

Calculate the actual distance of the fault point from one end of the cable based on the known propagation speed of the pulse signal in the cable.

Combine the cable installation path diagram and use the calculated distance information to initially determine the general location of the fault point.

Use supplementary methods such as electromagnetic induction and acoustic detection to further narrow the search area and directly determine the precise location of the fault point.

### 5. Fault Point Confirmation and Repair

After determining the fault point location, perform necessary excavation or inspection to confirm the specific condition of the fault point.

Depending on the type and severity of the fault, take appropriate repair measures, such as replacing the damaged part or repairing the joint.

After the repair is completed, perform necessary tests and verification to ensure that the cable is restored to normal operation.

### Characteristics of Technical Scheme

High Efficiency: compared with traditional manual detection methods, this method significantly shortens detection time and improves detection efficiency.

Accuracy: by utilizing time difference calculation and distance determination, precise localization of the fault point is achieved, reducing the possibilities of misjudgment and missed detection.

Non-Excavation: it avoids large-scale excavation and reduces manpower requirements, thereby lowering maintenance costs and minimizing environmental impact.

Applicability: it is applicable to underground buried power cables of various types, specifications, and materials, including but not limited to polyethylene insulated cables and cross-linked polyethylene insulated cables.

In summary, this technical scheme provides an efficient, accurate and non-excavation method for rapid detection of power cable faults, which is of great significance for ensuring the safe and stable operation of the power system.

The invention and its embodiments are described above, this description is not restrictive, and what is shown in the accompanying drawing is only one of the embodiments of the invention, and the actual structure is not limited to this. All in all, if those skilled in the art receives its enlightenment, without deviating from the object of the invention, and without creatively designing structures and embodiments similar to the technical scheme of the invention shall fall within the protection scope of the invention.

1. A method for rapid detection of power cable faults, comprising the following specific steps:
a) pulse signal emission: a high-frequency, short pulse signal is emitted into a power cable to be tested by using a pulse generator, the signal propagates along a cable conductor and reflects when it encounters a fault point, forming an echo signal;
b) echo signal reception: a receiver is placed at the other end of the cable or at an appropriate location, the receiver is used to capture the echo signal reflected from the fault point in the cable and record the time the pulse signal was transmitted and the time the echo signal was received;
c) time difference calculation and distance determination: based on the known propagation speed of the pulse signal in the cable, calculate the time difference between the transmitted pulse signal and the received echo signal, and then calculate the actual distance from the fault point to one end of the cable;
d) precise localization of the fault point: by combining a cable layout map and the distance information calculated in step c), along with auxiliary means such as electromagnetic induction and acoustic detection, further narrow down the search area to directly determine the precise location of the fault point.

2. The method for rapid detection of power cable faults of claim 1, wherein this method is applicable to underground buried power cables of various types, specifications, and materials.
